(19) United States
(12) Patent Application Publication
(10) Pub. No.: US 2020/0381889 A1
(43) Pub. Date: Dec. 3, 2020

(54) LIFE PREDICTION METHOD AND LIFE PREDICTION DEVICE FOR OPTICAL MODULE

(71) Applicant: Mitsubishi Electric Corporation, Tokyo (JP)

(72) Inventors: Takeshi SUEHIRO, Tokyo (JP); Kenichi NAKURA, Tokyo (JP); Hiromu SATO, Tokyo (JP); Kazuyuki ISHIDA, Tokyo (JP); Hideaki OHASHI, Tokyo (JP); Noriyuki IMADA, Tokyo (JP); Nanako HORAYAMA, Tokyo (JP)

(73) Assignee: Mitsubishi Electric Corporation, Tokyo (JP)

(21) Appl. No.: 16/995,292

(22) Filed: Aug. 17, 2020

Related U.S. Application Data
(63) Continuation of application No. PCT/JP2019/007889, filed on Feb. 28, 2019.

(30) Foreign Application Priority Data
Mar. 8, 2018 (JP) PCT/JP2018/009066

(51) Int. Cl. H01S 5/02; H01S 5/068; H04B 10/075

(52) U.S. Cl. CPC H01S 5/02; H04B 10/075; H01S 5/068

(57) ABSTRACT

A life prediction method for an optical module that keeps optical output constant by controlling a bias current that is applied to a laser diode includes, by a life prediction device: acquiring a current value of the bias current from the optical module; holding an initial bias current value that is an initial current value of the bias current; calculating the number of digits of a difference value between the bias current value and the initial bias current value, and determining whether there is an increase in the number of digits; calculating a time interval at which occurrence of the increase in the number of digits is detected; and estimating a life of the optical module using the time interval, a first threshold, and the number of digits.

### CROSS-REFERENCE TO RELATED APPLICATION

This application is a Continuation of PCT International Application No. PCT/JP2019/007889 filed on Feb. 28, 2019, which claims priority under 35 U.S.C. § 119(a) to Patent Application No. PCT/JP2018/009066 filed in Japan on Mar. 8, 2018, all of which are hereby expressly incorporated by reference into the present application.

### BACKGROUND OF THE INVENTION

### 1. Field of the Invention

The present disclosure relates to a life prediction method and a life prediction device for an optical module for predicting the life of the optical module that is used in optical communication.

### 2. Description of the Related Art

Optical communication has been applied to various systems because of its characteristics such as long transmission distance, high transmission speed, and high electromagnetic noise immunity. In a case where an optical communication system requires high reliability, an optical module that is used in the optical communication system also requires high reliability and needs preventive maintenance. An optical module includes a light source, and modulates and outputs light emitted from the light source using an electric signal generated according to information to be transmitted. An optical module that uses a laser diode as the light source typically has a function of keeping the optical output constant by controlling a bias current that is applied to the laser diode. The optical output decreases as the laser diode deteriorates even when an equal bias current is applied. Therefore, in order to keep the optical output constant, larger values of bias current should be applied as the laser diode deteriorates. Utilizing this principle, Patent Literature 1 discloses a technique for estimating the deterioration of a laser diode based on the value of bias current applied.

### CITATION LIST

### Patent Literature

Patent Literature 1: Japanese Patent Application Laid-open No. H09-116231

However, in the technique described in Patent Literature 1, the predictive value of the deterioration time, which is the time at which the laser diode is determined to have deteriorated, is obtained by linear approximation based on bias current values at two past times. For this reason, it is difficult to use the technique described in Patent Literature 1 to accurately estimate the life of an optical module, that is, the deterioration time of the laser diode. In a typical example, the bias current increases exponentially with elapsed time. In this case, according to the method described in Patent Literature 1, the deterioration time can be predicted with some degree of accuracy at a time near the true deterioration time, but the predictive value of the deterioration time deviates from the true deterioration time as the time at which the deterioration time is predicted is farther from the true time.

The present disclosure has been made in view of the above, and an object thereof is to provide a life prediction method for an optical module capable of predicting the life of the optical module quickly and accurately.

### SUMMARY OF THE INVENTION

The present disclosure provides a life prediction method for an optical module that keeps optical output constant by controlling a bias current that is applied to a laser diode, the method including, by a life prediction device, acquiring, from the optical module, a bias current value that is a current value of the bias current, and holding an initial bias current value that is an initial current value of the bias current. The life prediction method for an optical module further includes, by the life prediction device, calculating the number of digits of a difference value between the bias current value and the initial bias current value, and determining whether there is an increase in the number of digits, calculating a time interval at which occurrence of the increase in the number of digits is detected, and estimating a life of the optical module using the time interval, a first threshold, and the number of digits.

### BRIEF DESCRIPTION OF THE DRAWINGS

FIG. 1 is a diagram illustrating an exemplary configuration of a life prediction device according to a first embodiment.

FIG. 2 is a flowchart illustrating an exemplary procedure in the life prediction device according to the first embodiment.

FIG. 3 is a diagram illustrating an exemplary configuration of a life prediction device according to a second embodiment.

FIG. 4 is a flowchart illustrating an exemplary procedure in the life prediction device according to the second embodiment.

FIG. 5 is a diagram illustrating an exemplary configuration of a life prediction device according to a third embodiment.

FIG. 6 is a diagram illustrating an exemplary hardware configuration of a life prediction device.

FIG. 7 is a diagram illustrating another exemplary hardware configuration of a life prediction device.

FIG. 8 is a diagram illustrating an exemplary configuration of a life prediction device according to a fourth embodiment.

FIG. 9 is a diagram schematically illustrating a life prediction function F(T) that is based on the temperature characteristics of the laser according to the fourth embodiment.

FIG. 10 is a flowchart illustrating an exemplary procedure in the life prediction device according to the fourth embodiment.

### DETAILED DESCRIPTION OF THE PREFERRED EMBODIMENTS

Hereinafter, a life prediction method and a life prediction device for an optical module according to embodiments will be described in detail with reference to the drawings.

### First Embodiment

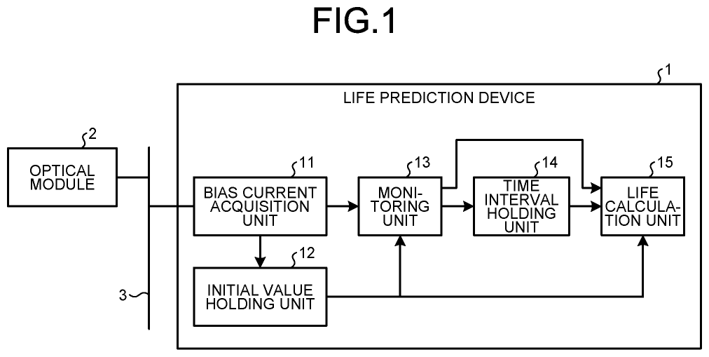

FIG. 1 is a diagram illustrating an exemplary configuration of a life prediction device 1 according to the first embodiment. As illustrated in FIG. 1, the life prediction device 1 of the present embodiment is connected to an optical module 2 by a bus 3. The optical module 2 includes a laser diode (not illustrated), and controls a bias current that is applied to the laser diode so as to keep the optical output constant. That is, the optical module 2 keeps the optical output constant by controlling a bias current that is applied to the laser diode. The bus 3 is, for example, an I2C bus, but the bus 3 is not limited to this. The form of connection between the optical module 2 and the life prediction device 1 is not limited to the connection using the bus 3.

As illustrated in FIG. 1, the life prediction device 1 includes a bias current acquisition unit 11, an initial value holding unit 12, a monitoring unit 13, a time interval holding unit 14, and a life calculation unit 15. The bias current acquisition unit 11 periodically acquires, from the optical module 2 via the bus 3, a bias current value, i.e. a current value of the bias current that is applied to the laser diode. Small form factor (SFF), which is a multi-source agreement (MSA: standards agreed between manufacturers) on optical modules, specifies that monitor information of an optical module including a bias current value can be acquired by an I2C interface. For example, the bias current acquisition unit 11 can acquire the bias current by acquiring monitor information according to the SFF and extracting a bias current value from the monitor information. The bias current acquisition unit 11 can periodically acquire the bias current using a timer that is reset every time a bias current value is acquired, for example. The bias current acquisition unit 11 outputs the bias current value indicated by the acquired bias current value information to the monitoring unit 13 and the initial value holding unit 12.

The initial value holding unit 12 holds an initial bias current value which is a current value of the initial bias current, and outputs the held initial bias current value to the monitoring unit 13 and the life calculation unit 15. In a case where the life prediction device 1 is started after the optical module 2 is turned on, the initial bias current value is the first bias current value received from the bias current acquisition unit 11 after the life prediction device 1 is started. In a case where the optical module 2 is turned on after the life prediction device 1 is started, the initial bias current value is the first bias current value received from the bias current acquisition unit 11 after the optical module 2 is turned on. Note that the initial bias current value is not limited to the examples described above, and may be any bias current value at the start of the life calculation processing.

The monitoring unit 13 obtains a difference value that is the difference between the bias current value output from the bias current acquisition unit 11 and the initial bias current value output from the initial value holding unit 12. The monitoring unit 13 detects the occurrence of a carry (described later) by monitoring the number of digits of the obtained difference value, and when a carry occurs, notifies the time interval holding unit 14 of the occurrence. A carry means that the number of digits of a current value is greater than the number of digits of a previous value. That is, the monitoring unit 13 calculates the number of digits of the difference value between the bias current value and the initial bias current value, and determines whether there is an increase in the number of digits. When a carry occurs, the monitoring unit 13 notifies the life calculation unit 15 of the number of digits of the difference value. The time interval holding unit 14 holds a timer for measuring the time interval at which a carry occurs, and calculates and holds the time interval for carry occurrence using the held timer, based on the notification from the monitoring unit 13. The time interval holding unit 14 notifies the life calculation unit 15 of the time interval for carry occurrence. The life calculation unit 15 calculates the remaining life of the optical module 2 as the life of the optical module 2 using the time interval for carry occurrence, the number of digits of the difference value, the threshold of the bias current, and the initial bias current value. The threshold of the bias current is the threshold of the bias current for determining that the optical module 2 has deteriorated. When the bias current is equal to or greater than this threshold, it is determined that the optical module 2 has deteriorated, that is, the optical module 2 has reached the end of its life. Details of the processing in the life calculation unit 15 will be described later.

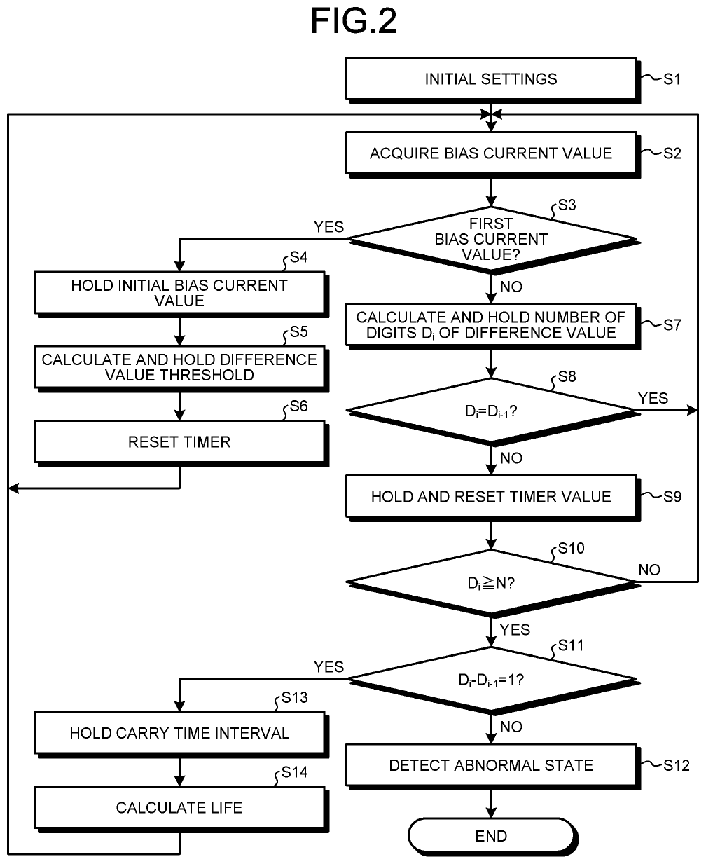

Next, a life prediction method for the optical module 2 by the life prediction device 1 of the present embodiment will be described. FIG. 2 is a flowchart illustrating an exemplary procedure in the life prediction device 1.

The life prediction device 1 first configures initial settings (step S1). As initial settings, the bias current threshold is set in the life calculation unit 15, and the effective carry threshold N is set in the monitoring unit 13. The bias current threshold may be set by the life calculation unit 15 reading the bias current threshold stored in advance in the life prediction device 1, or may be input from outside after the life prediction device 1 is started. Similarly, the effective carry threshold N may be set by the monitoring unit 13 reading the effective carry threshold N stored in advance in the life prediction device 1, or may be input from outside after the life prediction device 1 is started. Although the present embodiment describes an example in which the bias current threshold is set, a difference value threshold corresponding to a value obtained by subtracting the initial bias current value from the bias current threshold may be set in the life prediction device 1. In this case, step S5 described later need not be performed.

The bias current acquisition unit 11 of the life prediction device 1 acquires a bias current value from the optical module 2 (step S2). The life prediction device 1 determines whether the acquired bias current value is the first bias current value acquired by the bias current acquisition unit 11. In the case of the first bias current value (step S3: Yes), the life prediction device 1 holds the acquired bias current value as the initial bias current value (step S4). Specifically, when the acquired bias current value is the first bias current value acquired by the bias current acquisition unit 11, the bias current acquisition unit 11 passes the acquired bias current value to the initial value holding unit 12, and the initial value holding unit 12 holds the bias current value received from the bias current acquisition unit 11 as the initial bias current value. Alternatively, the bias current acquisition unit 11 passes the bias current value to the initial value holding unit 12 regardless of the number of bias current values acquired so far, and the initial value holding unit 12 holds the first bias current value acquired from the bias current acquisition unit 11 as the initial bias current value. The initial value holding unit 12 passes the initial bias current value to the life calculation unit 15.

The life calculation unit 15 calculates and holds the difference value threshold Dₗᵢₘᵢₜ by subtracting the initial bias current value from the bias current threshold (step S5). The time interval holding unit 14 resets the timer for measuring the time interval at which a carry occurs (step S6). Specifically, for example, step S6 is executed when the monitoring unit 13 instructs the time interval holding unit 14 to reset the timer in response to receiving the first bias current value from the bias current acquisition unit 11 that passes acquired bias current values to the monitoring unit 13. After step S6, the processing returns to step S2. As described above, because bias current values are acquired periodically, step S2 is periodically performed, and step S3 and subsequent steps are performed each time step S2 is performed.

When it is determined in step S3 that the acquired bias current value is not the first bias current value acquired by the bias current acquisition unit 11 (step S3: No), the monitoring unit 13 calculates and holds the number of digits Dᵢ of the difference value (step S7) The monitoring unit 13 holds the number of digits Dᵢ at least until the next execution of step S7. Here, “Dᵢ” is the number of digits of the difference value calculated using the i-th bias current acquired, where “i” is an integer indicating the total number of executions of step S2 including the latest execution. Because step S7 is executed after No is selected in step S3, step S7 is executed when i is two or more. In step S7, specifically, the monitoring unit 13 obtains a difference value by subtracting the initial bias current value output from the initial value holding unit 12 from the bias current acquired from the bias current acquisition unit 11, and calculates the number of digits Dᵢ of the obtained difference value. By managing the bias current value, the initial bias current value, and the difference value in binary notation, the calculation of the number of digits Dᵢ and the carry monitoring (described later) by hardware are facilitated.

The monitoring unit 13 determines whether the number of digits Dᵢ calculated in step S7 is equal to the number of digits Dᵢ₋₁ calculated and held in the previous step S7 (step S8). Note that in the case of i=2, Dᵢ₋₁, that is, D₁ has not been calculated. In the case of i=2, therefore, the monitoring unit 13 performs step S8 by assigning a preset value, e.g. zero, to D₁. When the number of digits Dᵢ is equal to the number of digits Dᵢ₋₁ (step S8: Yes), the life prediction device 1 returns to step S2.

When the number of digits Dᵢ is not equal to the number of digits Dᵢ₋₁ (step S8: No), the life prediction device 1 holds the timer value of the timer for measuring the time interval at which a carry occurs, and then resets the timer (step S9). Specifically, when No is selected in step S8, the monitoring unit 13 determines that a carry has been detected, notifies the time interval holding unit 14 of the detection of the carry, and notifies the life calculation unit 15 of the number of digits Dᵢ. In response to being notified of the detection of the carry, the time interval holding unit 14 holds the timer value of the internal timer and resets the timer. Here, based on the premise that the bias current increases with the passage of time, it is determined that a carry has occurred when the number of digits Dᵢ is not equal to the number of digits Dᵢ₋₁. If there is any abnormality such as an abnormality in data received from the optical module 2, the number of digits may be reduced. In such a case, No is selected in step S11 (described later), and an abnormal state is detected.

The monitoring unit 13 determines whether the number of digits Dᵢ is equal to or greater than the effective carry threshold N (step S10). When the number of digits Dᵢ is less than the effective carry threshold N (step S10: No), the processing returns to step S2. When the number of digits Dᵢ is equal to or greater than the effective carry threshold N (step S10: Yes), the monitoring unit 13 determines whether the value obtained by subtracting the number of digits Dᵢ₋₁ from the number of digits Dᵢ is one (step S11). When the value obtained by subtracting the number of digits Dᵢ₋₁ from the number of digits Dᵢ is not one (step S11: No), the monitoring unit 13 determines that the processing is in an abnormal state (step S12), and ends the processing. When it is determined that the processing is in an abnormal state, the monitoring unit 13 may transmit or display information for notifying the user of the abnormality.

When the value obtained by subtracting the number of digits Dᵢ₋₁ from the number of digits Dᵢ is one (step S11: Yes), the monitoring unit 13 instructs the time interval holding unit 14 to hold the time interval ΔT that is the time interval for carry, and the time interval holding unit 14 holds the timer value held in step S9 as the time interval ΔT (step S13). Note that the time interval holding unit 14 does not need to update the time interval ΔT when the timer value is the same as the held time interval ΔT. Further, the time interval holding unit 14 may keep holding the timer value obtained at the time of carry detection for a certain period of time, and calculate and hold the time interval ΔT by processing a plurality of held timer values. For example, the time interval holding unit 14 may calculate and hold the minimum value, average value, weighted average value, or the like of a plurality of held timer values as the time interval ΔT. Alternatively, the time interval holding unit 14 may set the average value of the previous time interval ΔT and the latest timer value as the time interval ΔT. The time interval holding unit 14 outputs the held time interval ΔT to the life calculation unit 15.

Next, the life calculation unit 15 calculates the remaining life of the optical module 2 using the difference value threshold Dₗᵢₘᵢₜ as a first threshold, the number of digits Dᵢ, and the time interval ΔT (step S14). After step S14, the processing returns to step S2. In step S14, specifically, the life calculation unit 15 calculates the remaining life T_{L} using Formula (1) below. The life calculation unit 15 may transmit information indicating the calculated remaining life T_{L} to the outside.

T_{L}=(Dₗᵢₘᵢₜ−Dᵢ)×ΔT (1)

The life prediction method for the optical module 2 according to the present embodiment includes a first step of acquiring a current value of the bias current from the optical module 2, and a second step of holding an initial bias current value that is an initial current value of the bias current performed by the life prediction device 1. The life prediction method for the optical module 2 according to the present embodiment also includes, by the life prediction device 1, a third step of calculating the number of digits of a difference value between the bias current value and the initial bias current value, and determining whether there is an increase in the number of digits. The life prediction method for the optical module 2 according to the present embodiment further includes, by the life prediction device 1, a fourth step of calculating the time interval ΔT that is a time interval at which occurrence of the increase in the number of digits is detected, and a fifth step of estimating a life of the optical module using the time interval ΔT, a first threshold, and the number of digits.

The bias current of the optical module 2 changes exponentially with time. In an exponential function, the number of digits changes linearly. In the present embodiment, as described above, the life prediction device 1 approximates the bias current with an exponential function with respect to time, thereby estimating the remaining life of the optical module 2 based on the number of digits of the difference value between the bias current and the initial bias current and the carry time interval for the difference value. Consequently, the remaining life of the optical module 2 can be estimated accurately, as compared with the case where the remaining life is calculated by linear approximation between two times.

Further, as described above, when the number of digits Dᵢ of the difference value is less than the effective carry threshold N, the life is not configured to be calculated. Consequently, a carry that may be caused by fluctuation in bias current values can be reduced from being erroneously recognized as a carry caused by deterioration of the optical module 2. When the difference value of the bias current value from the initial bias current is small, a carry is likely to occur due to fluctuation. Therefore, when the number of digits Dᵢ of the difference value is less than the effective carry threshold N, the life is not calculated, whereby a carry caused by fluctuation can be reduced from being erroneously recognized as a carry caused by deterioration.

### Second Embodiment

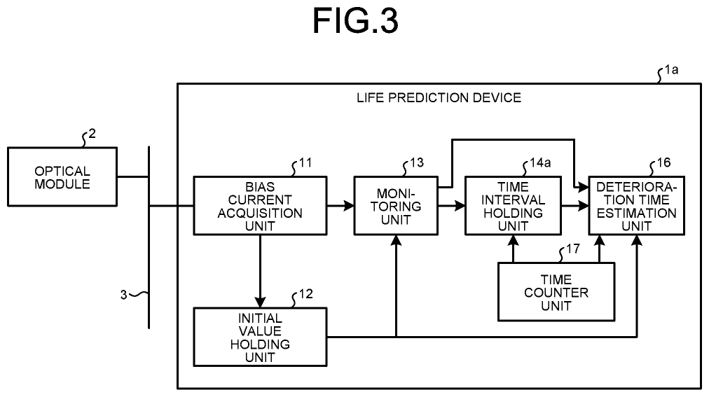

FIG. 3 is a diagram illustrating an exemplary configuration of a life prediction device according to the second embodiment. As illustrated in FIG. 3, the life prediction device 1a of the present embodiment is the same as the life prediction device 1 of the first embodiment except that it includes a time interval holding unit 14a, a deterioration time estimation unit 16, and a time counter unit 17 instead of the time interval holding unit 14 and the life calculation unit 15 of the first embodiment. Components having the same functions as those in the first embodiment are denoted by the same reference signs as those in the first embodiment, and redundant explanations are omitted. Hereinafter, differences from the first embodiment will be mainly described.

The time counter unit 17 outputs time information indicating the current time to the time interval holding unit 14a. In response to being notified of the detection of a carry by the monitoring unit 13, the time interval holding unit 14a holds the time of the notification of the carry detection based on the time information output from the time counter unit 17. In response to being notified of the detection of a carry by the monitoring unit 13, the time interval holding unit 14a also calculates and holds a time difference value, i.e. the difference value between the time of the notification of the carry detection and the time previously held, based on the time information output from the time counter unit 17. The time interval holding unit 14a also calculates and holds the time interval ΔT using the held time difference value. The time interval holding unit 14a may set the latest difference value as the time interval ΔT, or set the minimum value, average value, weighted average value, or the like of a plurality of held time difference values within a certain period of time as the time interval ΔT. Alternatively, the time interval holding unit 14a may set the average value of the previous time interval ΔT and the latest difference value as the time interval ΔT.

The deterioration time estimation unit 16 calculates and holds the difference value threshold Dₗᵢₘᵢₜ which is the threshold of the difference value between the bias current threshold, and the initial bias current value held by the initial value holding unit 12. As in the first embodiment, the bias current threshold may be set in advance in the life prediction device 1a, or may be set externally after the life prediction device 1a is started. Alternatively, the difference value threshold Dₗᵢₘᵢₜ may be set in the deterioration time estimation unit 16 instead of the bias current threshold.

The deterioration time estimation unit 16 estimates the estimated deterioration time of the optical module 2 as the life of the optical module 2 using the number of digits Dᵢ of the difference value calculated by the monitoring unit 13, the time interval ΔT held by the time interval holding unit 14a, and the time information output from the time counter unit 17.

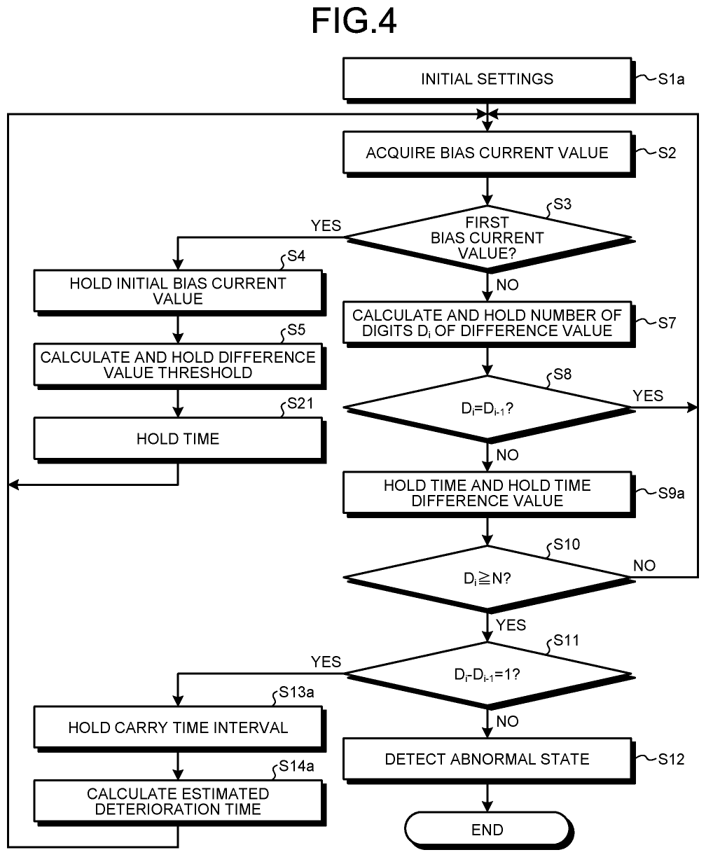

Next, a life prediction method for the optical module 2 by the life prediction device 1a of the present embodiment will be described. FIG. 4 is a flowchart illustrating an exemplary procedure in the life prediction device 1a.

First, the life prediction device 1a configures initial settings (step S1a). As initial settings, the bias current threshold is set in the deterioration time estimation unit 16, the effective carry threshold N is set in the monitoring unit 13, and the current time is set in the time counter unit 17.

Steps S2 to S5 are the same as those in the first embodiment. In the present embodiment, the data passed from each unit to the life calculation unit 15 in the first embodiment are passed to the deterioration time estimation unit 16 instead of the life calculation unit 15. Step S5 is performed by the deterioration time estimation unit 16 instead of the life calculation unit 15. After step S5, the time interval holding unit 14a holds the current time based on the time information acquired from the time counter unit 17 (step S21). After step S21, the processing returns to step S2.

When No is selected in step S3, steps S7 and S8 are performed as in the first embodiment. When No is selected in step S8, the time interval holding unit 14a holds the time, that is, the current time, based on the time information acquired from the time counter unit 17, and calculates and holds a time difference value, namely the difference value between the current time and the time previously held (step S9a). After step S9a, steps S10 and S11 are performed as in the first embodiment. Step S12 is also the same as that in the first embodiment.

When the value obtained by subtracting the number of digits Dᵢ₋₁ from the number of digits Dᵢ is one (step S11: Yes), the monitoring unit 13 instructs the time interval holding unit 14a to hold the time interval ΔT that is the time interval for carry, and the time interval holding unit 14a holds the time difference value held in step S9a as the time interval ΔT (step S13a). In the same manner as the time interval holding unit 14 of the first embodiment, the time interval holding unit 14a may hold the latest time difference value as the time interval ΔT, or may hold a plurality of time difference values to calculate the time interval ΔT from these time difference values or set the average value of these time difference values and the latest time difference value as the time interval ΔT.

The deterioration time estimation unit 16 calculates the estimated deterioration time T_{T} as the life of the optical module 2 using the difference value threshold Dₗᵢₘᵢₜ, the number of digits Dᵢ, the time interval ΔT, and the time t that is the time of the calculation of the life, namely the time indicated by the time information output from the time counter unit 17 (step S14a). After step S14a, the processing returns to step S2. In step S14a, specifically, the deterioration time estimation unit 16 calculates the estimated deterioration time T_{T} of the optical module 2 using Formula (2) below.

T_{T}=t+(Dₗᵢₘᵢₜ−Dᵢ)×ΔT (2)

As described above, in the present embodiment, as in the first embodiment, the bias current is approximated with an exponential function with respect to time, whereby the estimated deterioration time of the optical module 2 is estimated based on the number of digits of the difference value between the bias current and the initial bias current and the carry time interval for the difference value. Consequently, the estimated deterioration time of the optical module 2 can be estimated accurately, as compared with the case where the estimated deterioration time is calculated by linear approximation between two times. In addition, the estimated deterioration time of the optical module 2 is obtained by providing the time counter unit 17, which is especially effective when the life prediction device 1a cannot provide notification of a calculated value to the outside in real time.

### Third Embodiment

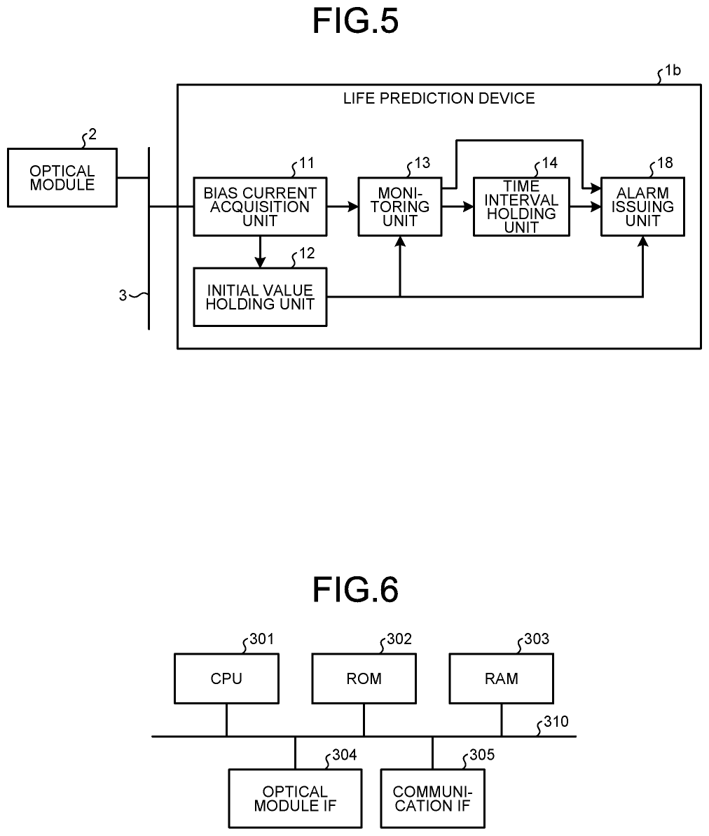

FIG. 5 is a diagram illustrating an exemplary configuration of a life prediction device according to the third embodiment. As illustrated in FIG. 5, the life prediction device 1b of the present embodiment is the same as the life prediction device 1 of the first embodiment except that it includes an alarm issuing unit 18 instead of the life calculation unit 15 of the first embodiment. Components having the same functions as those in the first embodiment are denoted by the same reference signs as those in the first embodiment, and redundant explanations are omitted. Hereinafter, differences from the first embodiment will be mainly described.

The alarm issuing unit 18 has a function as the life calculation unit 15 of the first embodiment and also has the alarm issuing function described below. That is, the function of the alarm issuing unit 18 corresponding to the life calculation unit 15 is the same as that in the first embodiment.

The alarm issuing unit 18 calculates the remaining life T_{L} using Formula (1) above as described in the first embodiment, and when the remaining life T_{L} is equal to or less than a preset threshold that is a second threshold, issues an alarm. An alarm may be issued, for example, by displaying an indication that the remaining life T_{L} is equal to or less than the threshold on a display unit (not illustrated), or by transmitting information indicating that the remaining life T_{L} is equal to or less than the threshold to an external device (not illustrated) through communication. The threshold about the remaining life T_{L} can be, for example, the maintenance cycle for the optical module 2. Alternatively, a plurality of such thresholds having different values may be set, and the alarm issuing unit 18 may indicate the extent of the remaining life T_{L} using the plurality of thresholds. For example, three thresholds A₁, A₂, and A₃ that satisfy A₁<A₂<A₃ (A₁, A₂, and A₃ are positive real numbers) are set for classifying the remaining life T_{L} as the first level equal to or less than A₃ and greater than A₂, the second level equal to or less than A₂ and greater than A₁, or the third level equal to or less than A₁. The alarm issuing unit 18 can provide the extent of the remaining life T_{L} to the outside by issuing information indicating which of the first, second, and third levels the remaining life T_{L} is at.

As described above, the alarm issuing unit 18 issues an alarm when the remaining life T_{L} is equal to or less than the threshold. Therefore, the amount of information transmitted to the outside can be reduced, as compared with the case where information indicating the remaining life T_{L} is transmitted to the outside every time the remaining life T_{L} is calculated.

Next, hardware configurations of the life prediction devices described in the first to third embodiments will be described. FIG. 6 is a diagram illustrating an exemplary hardware configuration of a life prediction device. The life prediction device includes a central processing unit (CPU) 301 as a processor, a read only memory (ROM) 302, a random access memory (RAM) 303, an optical module interface circuit (optical module IF) 304, and a communication interface circuit (communication IF) 305. These components are connected by a bus 310. The CPU 301 controls the entire life prediction device. The ROM 302 stores programs such as a boot program, a communication program, and a data analysis program. The ROM 302 stores a program for implementing the function as the life prediction device of the present embodiment, and the CPU 301 executes the program, whereby the operation of each unit of the life prediction device illustrated in FIGS. 1, 3, and 5 is implemented. The RAM 303 is used as a work area of the CPU 301. The optical module IF 304 functions as an interface for acquiring the bias current of the optical module. The communication IF 305 functions as an interface between the life prediction device and the outside.

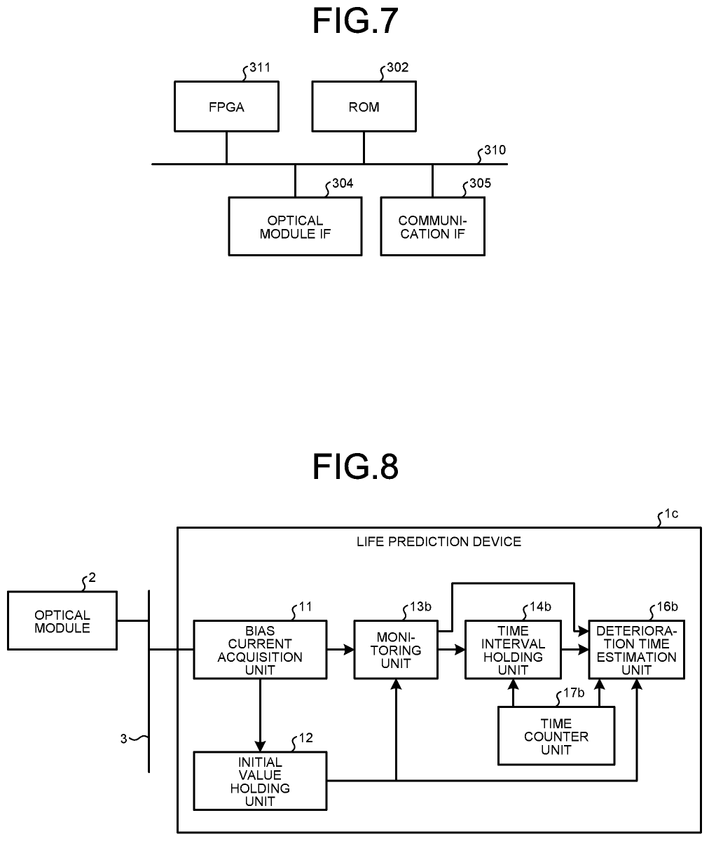

FIG. 7 is a diagram illustrating another exemplary hardware configuration of a life prediction device. The life prediction device includes a field programmable gate array (FPGA) 311, the ROM 302, the optical module IF 304, and the communication IF 305. These components are connected by the bus 310. The FPGA 311 controls the entire life prediction device. The ROM 302 stores a program for the FPGA 311. The ROM 302 may not be required depending on the type of the FPGA 311. The operation of each unit of the life prediction device illustrated in FIGS. 1, 3, and 5 is implemented by the FPGA 311. The optical module IF 304 functions as an interface for acquiring the bias current of the optical module. The communication IF 305 functions as an interface between the life prediction device and the outside. Note that some of the units of the life prediction device illustrated in FIGS. 1, 3, and 5 may be implemented using the CPU 301, and the rest may be implemented by the FPGA 311.

### Fourth Embodiment

FIG. 8 is a diagram illustrating an exemplary configuration of a life prediction device according to the fourth embodiment. As illustrated in FIG. 8, the life prediction device 1c of the present embodiment is the same as the life prediction device 1a of the second embodiment except that it includes a monitoring unit 13b, a time interval holding unit 14b, a deterioration time estimation unit 16b, and a time counter unit 17b instead of the monitoring unit 13, the time interval holding unit 14a, the deterioration time estimation unit 16, and the time counter unit 17 of the second embodiment. Components having the same functions as those in the second embodiment are denoted by the same reference signs as those in the second embodiment, and redundant explanations are omitted. Hereinafter, differences from the second embodiment will be mainly described.

The monitoring unit 13b performs detection of the maximum value of the bias current output from the bias current acquisition unit 11 within a fixed cycle, in addition to detection of a carry, notification of the carry detection, and notification of the number of digits as described in the second embodiment. That is, the monitoring unit 13b calculates the maximum bias current value within a fixed cycle of bias current values in each fixed cycle. The monitoring unit 13b also notifies the time interval holding unit 14b of the detection of the maximum bias current value, and notifies the deterioration time estimation unit 16b of the maximum bias current value. Note that the monitoring unit 13b compares, for example, the first bias current value and the second bias current value detected within a fixed cycle, and notifies the time interval holding unit 14b of the larger one as the temporary maximum value. The time interval holding unit 14b temporarily holds the time of the notification of the maximum value based on the time information output from the time counter unit 17b. Thereafter, the monitoring unit 13b sequentially compares the next bias current value detected and the current maximum value within the fixed cycle, and when the detected bias current value is larger, notifies the time interval holding unit 14b of the detection of the maximum value. Then, when the one fixed cycle ends, the monitoring unit 13b notifies the time interval holding unit 14b of the end of the fixed cycle. Consequently, the time interval holding unit 14b determines the detection time of the maximum value in this fixed cycle. Note that the method of calculating the maximum value detection time in a fixed cycle is not limited to the above-described example.

The time counter unit 17b outputs time information indicating the current time to the time interval holding unit 14b. In response to being notified of the detection of a carry by the monitoring unit 13b, the time interval holding unit 14b holds the time of the notification of the carry detection based on the time information output from the time counter unit 17b. In response to being notified of the detection of a carry by the monitoring unit 13b, the time interval holding unit 14b also calculates and holds the time interval ΔT using a time difference value, namely the difference value between the time of the notification of the carry detection and the carry time previously held, based on the time information output from the time counter unit 17b. The time interval holding unit 14b also calculates and holds the time interval ΔT using the held time difference value. The time interval holding unit 14b may hold the latest difference value as the time interval ΔT, or may store a plurality of time difference values within a fixed period of time to hold the minimum value, average value, weighted average value, or the like of the plurality of stored time difference values as the time interval ΔT. The time interval holding unit 14b may hold the average value of the previous time interval ΔT and the latest difference value as the time interval ΔT.

When being notified of the detection of a maximum bias current value by the monitoring unit 13b, the time interval holding unit 14b also holds the time of the notification of the maximum bias current value detection based on the time information output from the time counter unit 17b. The time interval holding unit 14b also outputs, in each fixed cycle, the time of the notification of the maximum bias current value detection to the deterioration time estimation unit 16b as the maximum value detection time. As described above, the monitoring unit 13b detects the maximum bias current value in a fixed cycle, so the time interval holding unit 14b can obtain one maximum value detection time per fixed cycle from the monitoring unit 13b.

The deterioration time estimation unit 16b calculates and holds the difference value threshold Dₗᵢₘᵢₜ which is the threshold of the difference value between the bias current threshold and the initial bias current value held by the initial value holding unit 12. As in the second embodiment, the bias current threshold may be set in advance in the life prediction device 1c, or may be set externally after the life prediction device 1c is started. Alternatively, the difference value threshold Dₗᵢₘᵢₜ may be set in the deterioration time estimation unit 16b instead of the bias current threshold.

The deterioration time estimation unit 16b estimates the first estimated deterioration time T_{T1} of the optical module 2 as the life of the optical module 2 using the number of digits Dᵢ of the difference value calculated by the monitoring unit 13b, the time interval ΔT held by the time interval holding unit 14b, and the time information output from the time counter unit 17b. The method of calculating the first estimated deterioration time T_{T1} is the same as the method of calculating the estimated deterioration time described in the second embodiment.

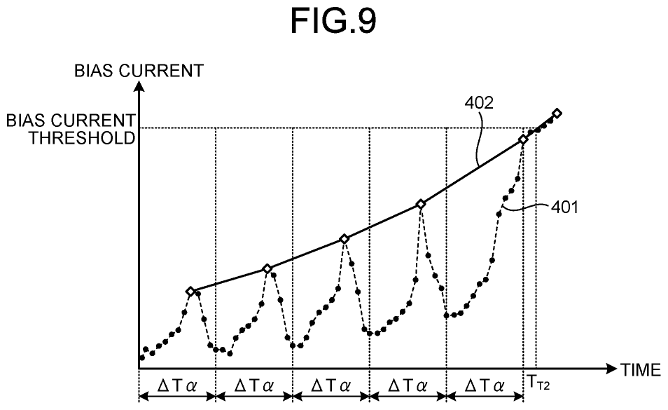

The deterioration time estimation unit 16b also estimates the estimated deterioration time of the optical module 2 based on the maximum bias current value within a fixed cycle of bias current values and the time of the detection of the maximum bias current value. Specifically, using the maximum bias current value provided by the monitoring unit 13b and the maximum value detection time output from the time interval holding unit 14b, the deterioration time estimation unit 16b calculates a life prediction function F(T) that is based on the temperature characteristics of the laser caused by temperature changes on a daily basis or a seasonal basis. FIG. 9 is a diagram schematically illustrating the life prediction function F(T) that is based on the temperature characteristics of the laser according to the fourth embodiment. In FIG. 9, the horizontal axis represents time, and the vertical axis represents bias current. The bias current 401 indicates the bias current acquired by the bias current acquisition unit 11. The fixed cycle ΔTα is a cycle in which the monitoring unit 13b detects a maximum bias current value. That is, the monitoring unit 13b detects the maximum bias current value output from the bias current acquisition unit 11 in each fixed cycle ΔTα. The approximate curve 402 is an approximate curve that approximates the relationship between time and bias current using the maximum bias current value output from the monitoring unit 13b and the maximum value detection time output from the time interval holding unit 14b. The life prediction function F(T) that is based on the temperature characteristics of the laser is represented by this approximate curve 402.

The deterioration time estimation unit 16b estimates the second estimated deterioration time T_{T2} of the optical module 2 using the calculated life prediction function F(T) that is based on the temperature characteristics of the laser and the bias current threshold. Specifically, the deterioration time estimation unit 16b obtains the time at which the value of the life prediction function F(T) that is based on the temperature characteristics of the laser is equal to the bias current threshold, and sets the obtained time as the second estimated deterioration time T_{T2}.

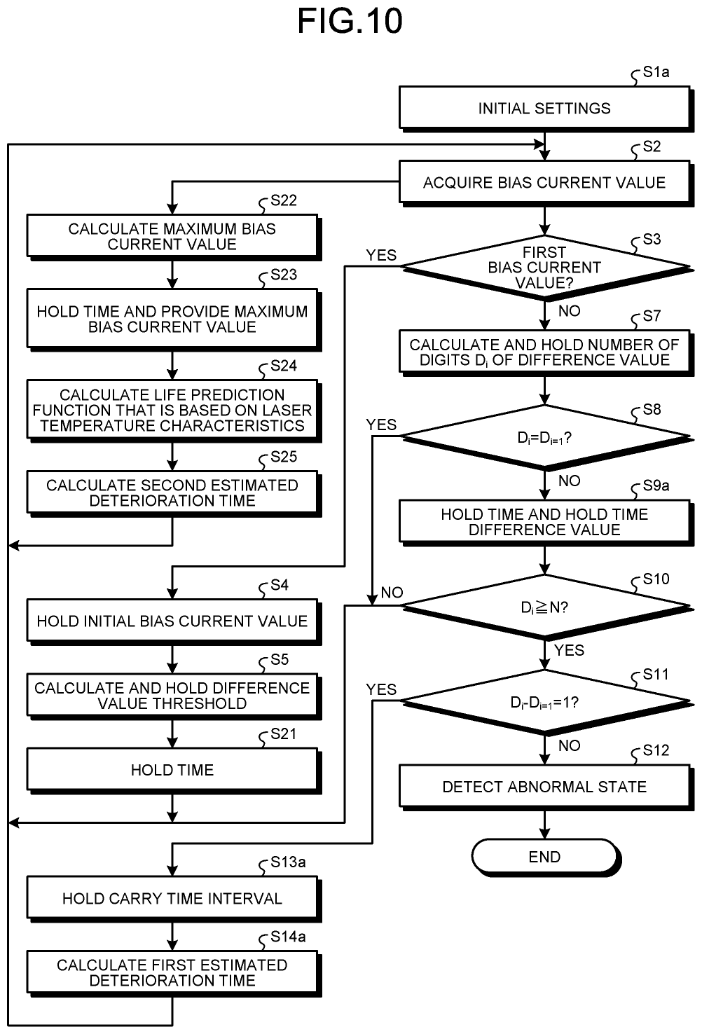

Next, a life prediction method for the optical module 2 by the life prediction device 1c of the present embodiment will be described. FIG. 10 is a flowchart illustrating an exemplary procedure in the life prediction device 1c according to the fourth embodiment.

First, the life prediction device 1c configures initial settings (step S1a). As initial settings, the bias current threshold is set in the deterioration time estimation unit 16b, the effective carry threshold N is set in the monitoring unit 13b, and the current time is set in the time counter unit 17b.

Steps S2 to S5 are the same as those in the second embodiment. In the present embodiment, the data passed from each unit to the deterioration time estimation unit 16 in the second embodiment are passed to the deterioration time estimation unit 16b instead of the deterioration time estimation unit 16. Step S5 is performed by the deterioration time estimation unit 16b instead of the deterioration time estimation unit 16. After step S5, the time interval holding unit 14b holds the current time based on the time information acquired from the time counter unit 17b (step S21). After step S21, the processing returns to step S2.

When No is selected in step S3, steps S7 and S8 are performed as in the second embodiment. When No is selected in step S8, the time interval holding unit 14b holds the time, that is, the current time, based on the time information acquired from the time counter unit 17b, and calculates and holds a time difference value, namely the difference value between the current time and the time previously held (step S9a). After step S9a, steps S10 and S11 are performed as in the second embodiment. Step S12 is also the same as that in the second embodiment.

When the value obtained by subtracting the number of digits Dᵢ₋₁ from the number of digits Dᵢ is one (step S11: Yes), the monitoring unit 13b instructs the time interval holding unit 14b to hold the time interval ΔT that is the time interval for carry, and the time interval holding unit 14b holds the time difference value held in step S9a as the time interval ΔT (step S13a). In the same manner as the time interval holding unit 14a of the second embodiment, the time interval holding unit 14b may hold the latest time difference value as the time interval ΔT, or may hold a plurality of time difference values to calculate the time interval ΔT from these time difference values or set the average value of these time difference values and the latest time difference value as the time interval ΔT.

The deterioration time estimation unit 16b calculates the first estimated deterioration time T_{T1} as the life of the optical module 2 using the difference value threshold Dₗᵢₘᵢₜ, the number of digits Dᵢ, the time interval ΔT, and the time t that is the time of the calculation of the life, namely the time indicated by the time information output from the time counter unit 17b (step S14a). After step S14a, the processing returns to step S2. In step S14a, specifically, the deterioration time estimation unit 16b calculates the first estimated deterioration time T_{T1} of the optical module 2 using Formula (3) below.

T_{T1}=t+(Dₗᵢₘᵢₜ−Dᵢ)×ΔT (3)

After step S2, step S22 is performed in parallel with step S3. Step S22 is the process in which the monitoring unit 13b calculates the maximum bias current value within a fixed cycle output from the bias current acquisition unit 11. After step S22, step S23 is performed.

In step S23, the time interval holding unit 14b holds the time, that is, the time of the calculation of the maximum value, based on the time information acquired from the time counter unit 17b. The maximum bias current value calculated by the monitoring unit 13b is provided to the deterioration time estimation unit 16b. After step S23, step S24 is performed.

In step S24, the deterioration time estimation unit 16b calculates the life prediction function F(T) that is based on the temperature characteristics of the laser using the maximum bias current value provided by the monitoring unit 13b and the time information of the notification of the maximum bias current value detection output from the time interval holding unit 14b. After step S24, step S25 is performed.

In step S25, the deterioration time estimation unit 16b calculates the second estimated deterioration time T_{T2} of the optical module 2 using the life prediction function F(T) that is based on the temperature characteristics of the laser calculated in step S24 and the bias current threshold set in step S1a.

In the above example, after step S2, the life prediction device 1c performs both the process that starts at step S3, that is, the process similar to that in the second embodiment, and the process of steps S22 to S25. Alternatively, only the process of steps S22 to S25 may be performed after step S2. As described above, the life prediction method for an optical module according to the present embodiment includes a step of calculating a maximum bias current value within a fixed cycle of the bias current values in each fixed cycle, and a step of estimating an estimated deterioration time of the optical module based on the maximum bias current value and a time of detection of the maximum bias current value.

As described above, in the present embodiment, as in the second embodiment, the bias current is approximated with an exponential function with respect to time, whereby the estimated deterioration time of the optical module 2 is estimated based on the number of digits of the difference value between the bias current and the initial bias current and the carry time interval for the difference value. Consequently, the estimated deterioration time of the optical module 2 can be estimated accurately, as compared with the case where the estimated deterioration time is calculated by linear approximation between two times. In addition, the estimated deterioration time of the optical module 2 is obtained by providing the time counter unit 17b, which is especially effective when the life prediction device 1c cannot provide notification of a calculated value to the outside in real time. Further, the life prediction function F(T) that is based on the temperature characteristics of the laser is calculated on the basis of the maximum bias current value and the time information of the notification of the maximum bias current value detection, and the estimated deterioration time of the optical module 2 is estimated on the basis of the life prediction function F(T) that is based on the temperature characteristics of the laser and the bias current threshold. Consequently, the estimated deterioration time can be calculated in consideration of the temperature characteristics of the laser.

The configurations described in the above-mentioned embodiments indicate examples. The configurations can be combined with another well-known technique, and some of the configurations can be omitted or changed in a range not departing from the gist.

The present disclosure can achieve the effect of predicting the life of the optical module quickly and accurately.

What is claimed is:

1. A life prediction method for an optical module, the optical module being configured to keep optical output constant by controlling a bias current that is applied to a laser diode, the method comprising, by a life prediction device:
acquiring, from the optical module, a bias current value that is a current value of the bias current;
holding an initial bias current value that is an initial current value of the bias current;
calculating a number of digits of a difference value between the bias current value and the initial bias current value, and determining whether there is an increase in the number of digits;
calculating a time interval at which occurrence of the increase in the number of digits is detected; and
estimating a life of the optical module using the time interval, a first threshold, and the number of digits.

2. The life prediction method for an optical module according to claim 1, wherein the life is a remaining life of the optical module.

3. The life prediction method for an optical module according to claim 2, comprising
issuing an alarm when the remaining life is equal to or less than a second threshold set in advance.

4. The life prediction method for an optical module according to claim 1, wherein
the life is an estimated deterioration time of the optical module, and
in the estimating the life of the optical module, the estimated deterioration time is estimated using the time interval, the first threshold, the number of digits, and a time of calculation of the life.

5. The life prediction method for an optical module according to claim 1, comprising:
calculating a maximum bias current value within a fixed cycle of the bias current values in each fixed cycle; and
estimating an estimated deterioration time of the optical module based on the maximum bias current value and a time of detection of the maximum bias current value.

6. A life prediction method for an optical module, the optical module being configured to keep optical output constant by controlling a bias current that is applied to a laser diode, the method comprising, by a life prediction device:
acquiring, from the optical module, a bias current value that is a current value of the bias current;
holding an initial bias current value that is an initial current value of the bias current;
calculating a maximum bias current value within a fixed cycle of the bias current values in each fixed cycle; and
estimating an estimated deterioration time of the optical module based on the maximum bias current value and a time of detection of the maximum bias current value.

7. A life prediction device that predicts a life of an optical module, the optical module being configured to keep optical output constant by controlling a bias current that is applied to a laser diode, the life prediction device comprising:
a memory; and
a processor and/or a field programmable gate array configured to:
acquire, from the optical module, a bias current value that is a current value of the bias current;
hold an initial bias current value that is an initial current value of the bias current;
calculate a number of digits of a difference value between the bias current value and the initial bias current value, and determine whether there is an increase in the number of digits;
calculate a time interval at which occurrence of the increase in the number of digits is detected; and
estimate the life of the optical module using the time interval, a first threshold, and the number of digits.

8. The life prediction device according to claim 7, wherein the life is a remaining life of the optical module.

9. The life prediction device according to claim 8, wherein an alarm is issued when the remaining life is equal to or less than a second threshold set in advance.

10. The life prediction device according to claim 7, wherein
the life is an estimated deterioration time of the optical module, and
the processor and/or a field programmable gate array estimates the estimated deterioration time using the time interval, the first threshold, the number of digits, and a time of calculation of the life.

11. The life prediction device according to claim 7, wherein the processor and/or a field programmable gate array estimates an estimated deterioration time of the optical module based on a maximum bias current value within a fixed cycle of the bias current values and a time of detection of the maximum bias current value in each fixed cycle.

12. A life prediction device that predicts a life of an optical module, the optical module being configured to keep optical output constant by controlling a bias current that is applied to a laser diode, the life prediction device comprising:
a memory; and
a processor and/or a field programmable gate array configured to:
acquire, from the optical module, a bias current value that is a current value of the bias current;
calculate a maximum bias current value within a fixed cycle of the bias current values in each fixed cycle; and
estimate an estimated deterioration time of the optical module based on the maximum bias current value and a time of detection of the maximum bias current value.
